(19) United States
(12) Patent Application Publication
(10) Pub. No.: US 2025/0363004 A1
(43) Pub. Date: Nov. 27, 2025

(54) INTERNAL ERROR CORRECTION SEQUENCES FOR A MEMORY DEVICE

(71) Applicant: Micron Technology, Inc., Boise, ID (US)

(72) Inventors: Melky Arputharaja SILUVAINATHAN, San Jose, CA (US); Andrew DANILOVIC, Collegeville, PA (US); Ankush LAL, Sunnyvale, CA (US)

(21) Appl. No.: 19/209,287

(22) Filed: May 15, 2025

Related U.S. Application Data
(60) Provisional application No. 63/650,176, filed on May 21, 2024.

(51) Int. Cl. G06F 11/10; G06F 11/14

(52) U.S. Cl. CPC G06F 11/1068; G06F 11/1004; G06F 11/1441

(57) ABSTRACT

In some implementations, a memory device may determine that the memory device has encountered an internal error that requires an internal reset of at least one component of the memory device. The memory device may transmit, to a host device, a first-stage notification indicating that the memory device has encountered the internal error. The memory device may save diagnostic data associated with the internal error to a nonvolatile storage component of the memory device. The memory device may perform a first-stage reset of a first set of internal memory device subsystems based on saving the diagnostic data to the nonvolatile storage component. The memory device may transmit, to the host device after the first-stage notification and based on performing the first-stage reset, a second-stage notification indicating that the host device is to perform a memory device reset procedure.

### CROSS-REFERENCE TO RELATED APPLICATION

This Patent application claims priority to U.S. Provisional Patent Application No. 63/650,176, filed on May 21, 2024, entitled “INTERNAL ERROR CORRECTION SEQUENCES FOR A MEMORY DEVICE,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to internal error correction sequences for a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a compute express link (CXL). For example, the memory device may be a CXL compliant memory device and/or may include a CXL interface.

### BRIEF DESCRIPTION OF THE DRAWINGS

FIG. 1 is a diagram illustrating an example system capable of implementing internal error correction sequences for a memory device.

FIG. 2 is a diagram illustrating another example system capable of implementing internal error correction sequences for a memory device.

FIGS. 3A-3C are diagrams of examples associated with internal error correction sequences for a memory device.

FIG. 4 is a flowchart of an example method associated with internal error correction sequences for a memory device.

FIG. 5 is a flowchart of another example method associated with internal error correction sequences for a memory device.

FIG. 6 is a flowchart of another example method associated with internal error correction sequences for a memory device.

### DETAILED DESCRIPTION

In some examples, a memory device may be configured to detect and/or handle internal errors, such as by initiating a firmware panic sequence. “Firmware panic sequence” may refer to a series of actions and/or events triggered by firmware of the device when the device encounters a critical error or fault that cannot be corrected through a normal progression of the firmware. In some examples, a memory device may detect an internal error (e.g., a critical error), such as an error due to hardware failure, corrupted data, and/or other issues that compromise the integrity and/or functionality of the memory device. The memory device (e.g., firmware of the memory device) may thus initiate a panic sequence, which may be a sequence designed to prevent further damage and/or data loss and/or to notify a user about the critical error. In some cases, the firmware may halt ongoing operations and/or processes that may lead to further errors, such as by stopping data transfers, disabling write operations, putting the memory device into a safe state, and/or similar operations. Moreover, the firmware may log information about the error, such as by saving details (e.g., in a nonvolatile storage), such as error codes, timestamps, and/or other diagnostic information that may later be used to help identify the root cause of the problem. In some examples, the firmware may notify a user about the error, such as by providing a visual indication (e.g., via lights associated with the memory device) and/or by transmitting certain indications via system logs, among other examples. Moreover, the firmware may attempt to recover from the error condition, such as by resetting the memory device, performing internal diagnostics and/or self-tests, attempting to restore the memory device to a known good state, and/or performing similar operations.

In some examples, notwithstanding the above procedures and/or similar panic sequence operations, a memory device panic sequence may result in silent data corruption, cascading errors, and/or similar errors at the memory device and/or a connected host device. For example, any data sent from a memory device to a host device after an internal error has been detected and prior to an appropriate error recovery sequence occurring may be invalid due to the error condition which caused the device firmware panic sequence to be initiated. However, prior to completion of certain error handling operations, the host device may be unaware that the data is corrupted, resulting in silent data corruption at the host device. On the other hand, in cases in which the memory device immediately ceases transmission of data to the host device in response to detecting an internal error, the ceased transmissions may result in repeated host command timeouts at the host device, resulting in error cascading and thus more difficult failure analysis and/or error recovery procedures.

Moreover, logging error information, such as by saving diagnostic data in nonvolatile storage, may be time-consuming, resource-intensive, and/or unavailable due to the nature of the internal error. For example, logging diagnostic data (sometimes referred to herein as performing a panic dump) may be implemented using page-addressable nonvolatile memory that requires endurance management. In such examples, endurance management may be provided by a flash translation layer (FTL), and thus in order to store a panic dump into the page-addressable nonvolatile memory, recovery of the FTL firmware may be required. Recovery of the FTL firmware may be performed by rebooting of one or more memory device central processing units (CPUs), which may be a time-intensive and/or resource-intensive process. Moreover, rebooting one or more CPUs may require firmware to be executed in hardware that caused that firmware panic sequence to be initiated, which may thus fail as the memory device attempts to initialize hardware that is in a failure state. In such cases, the panic dump may not be saved, resulting in an inability to diagnose the internal error and/or resulting in the memory device experiencing similar internal errors in the future.

Additionally, or alternatively, in some examples a memory device (e.g., a compute express link (CXL) compliant memory device) may be a device that is coherent with a processor (e.g., a host device), and thus may be treated as another processor package, among other examples. In such examples, the memory device may be associated with a fabric manager, and/or a notification may need to be provided to a fabric manager prior to a managed hot removal and/or a sudden removal of the memory device to avoid a host device panic and/or crash. In some other examples, a memory device may be a single logical device (SLD) or a dual ported device that is not associated with a fabric manager, and thus a sudden removal condition may need to be avoided altogether to avoid a host device panic and/or crash. However, certain processes of the firmware panic sequence may result in a sudden removal condition without a notification to a fabric manager. For example, the memory device firmware may initiate a panic sequence in response to detecting a problem in a host interface management component. In such examples, resetting the host interface management component (sometimes referred to herein as a host interface module) in an effort to recover from the internal error may result in a sudden removal condition that may cause a host device panic and/or crash.

Some implementations described herein enable improved memory device internal error handling sequences (e.g., improved firmware panic sequences), such as by enabling internal error handling sequences that result in reduced silent data corruption, reduced cascading errors, improved panic dump saving operations resulting in more reliable diagnostic information and/or reduced time and/or resource consumption associated with diagnostic procedures, and/or reduced sudden removal conditions, thereby reducing occurrences of host device panic and/or crashes. In some implementations, a memory device may be configured to utilize a two-stage notification procedure, such as by, in response to determining that the memory device has encountered an internal error, transmitting a first-stage notification to a host device indicating that the memory device has encountered the internal error, and then transmitting a second-stage notification after performing certain internal error handling steps. In this way, the memory device may continue to transmit data (e.g., flits) to the host device during an internal handling procedure to avoid host command timeouts and/or similar cascading errors, while notifying the host device early in the internal error handling sequence that an error has occurred in order to avoid silent data corruption.

Additionally, or alternatively, a two-stage notification procedure may enable the memory device to complete certain time-consuming steps (e.g., a step associated with saving diagnostic data save to nonvolatile byte-addressable memory and/or a step associated with performing or first stage internal reset, among other time-consuming steps) prior to any notification stages that are associated with certain time limits. For example, a Peripheral Component Interconnect Express (PCIe) warm reset needed notification (which, in some examples, may correspond to a second-stage host notification step described herein), may commence a PCIe specification required timeout, within which the memory device may be required to return to normal operation. In such examples, completing the diagnostic data save step before the PCIe warm reset needed notification step may enable the memory device to complete the PCIe warm reset sequence within the PCIe specification required time limit.

Additionally, or alternatively, a memory device may be configured to store diagnostic data (e.g., a panic dump) associated with the internal error handling procedure to a byte-addressable nonvolatile storage component associated with the memory device. In some implementations, the byte-addressable nonvolatile storage component may not require endurance management, thus removing a need to fix an FTL after initiating a firmware panic sequence and/or a need to reboot a CPU after initiating a firmware panic sequence, thereby reducing a complexity of procedures associated with saving diagnostic data and thus reducing power, computing, and other resource consumption associated with saving diagnostic data, and/or resulting in more reliable diagnostic procedures and thus improved memory device operations.

Additionally, or alternatively, a memory device may be configured to classify a type of internal reset required to recover from an internal error, and/or to select a certain reset level that is to be performed based on the type of internal reset required.

For example, the memory device may be configured to select one or more of a first level reset, which may be associated with resetting certain non-host-interface-management components of the memory device, and/or a second level reset, which may be associated with resetting the host-interface-management components of the memory device. In this way, the memory device may avoid resetting host-interface-management components of the memory device when an internal error is not related to a host interface module and/or when a fabric manager is not available, thereby reducing instances of a sudden removal condition and/or instances of the firmware panic sequence triggering a host device panic and/or crash, and thus reducing power, computing, and/or other resource consumption otherwise required to unnecessarily reset the host interface module and/or to recover from unnecessarily triggered host device panics and/or crashes.

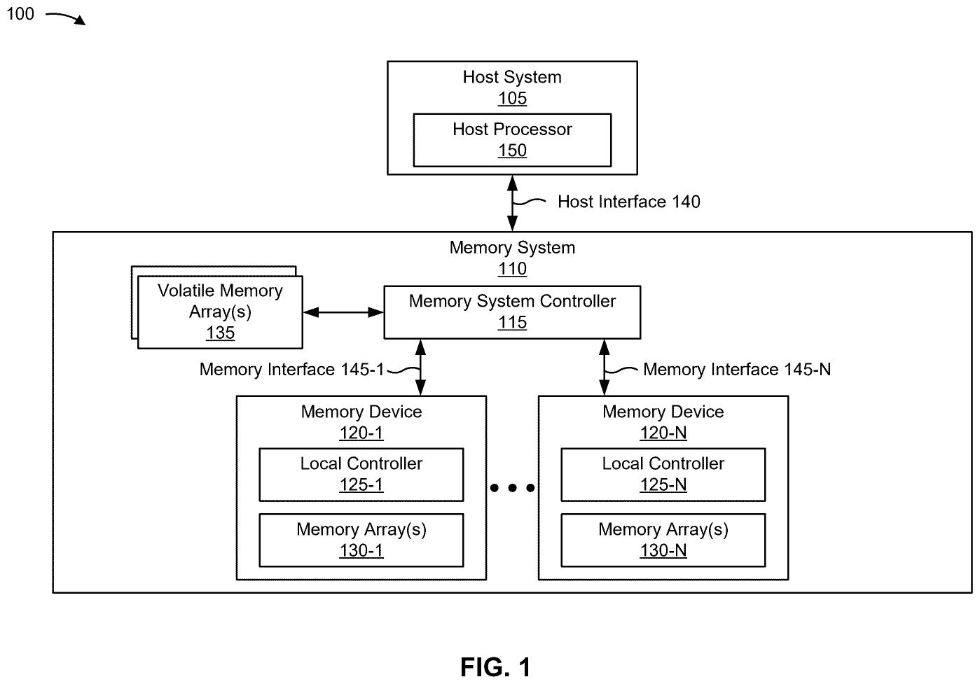

FIG. 1 is a diagram illustrating an example system 100 capable of implementing internal error correction sequences for a memory device. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N(where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N(where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), a CXL memory module, and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, a compute express link (CXL) controller connected to DRAM, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

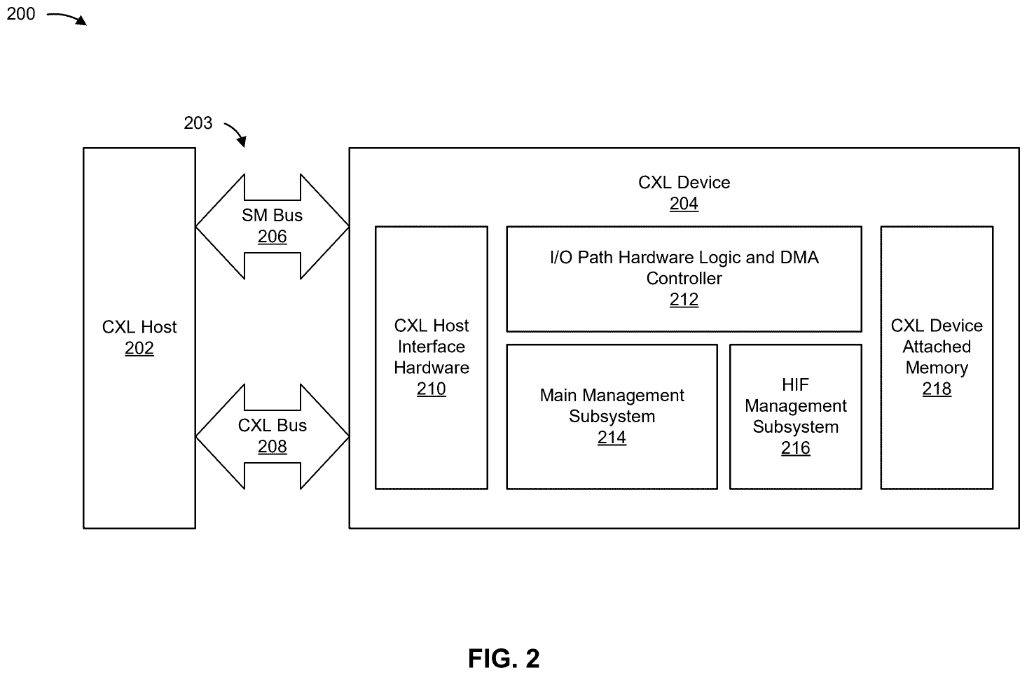

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a PCIe interface, an NVMe interface, a USB interface, a Universal Flash Storage (UFS) interface, an eMMC interface, a double data rate (DDR) interface, a DIMM interface, and/or a CXL interface (e.g., a PCIe/CXL interface, described in more detail below in connection with FIG. 2).

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to determine that a memory device has encountered an internal error that requires an internal reset of at least one component of the memory device; transmit, to a host device, a first-stage notification indicating that the memory device has encountered the internal error; save diagnostic data associated with the internal error to a nonvolatile storage component of the memory device; perform a first-stage reset of a first set of internal memory device subsystems; and transmit, to the host device after the first-stage notification and based on performing the first-stage reset, a second-stage notification indicating that the host device is to perform a memory device reset procedure.

In some implementations, one or more systems, devices, apparatuses, components, and/or controllers of FIG. 1 may be configured to determine that a memory device has encountered an internal error that requires an internal reset of at least one component of the memory device; transmit a first-stage notification indicating that the memory device has encountered the internal error; save diagnostic data associated with the internal error to a byte-addressable nonvolatile storage component of the memory device; perform a first-stage reset of a first set of internal memory device subsystems; and transmit, after the first-stage notification and based on performing the first-stage reset, a second-stage notification indicating that the host device is to perform a memory device reset procedure.

In some implementations, one or more systems, devices, apparatuses, components, and/or controllers of FIG. 1 may be configured to determine that a CXL memory module has encountered an internal error that requires an internal reset of at least one component of the CXL memory module; transmit, to a host system, a first-stage notification indicating that the CXL memory module has encountered the internal error; save diagnostic data associated with the internal error to a nonvolatile storage component of the CXL memory module; determine a type of the internal reset that is to be performed; select one or more reset levels, of multiple potential reset levels, to be used for the internal reset based on determining the type of the internal reset that is to be performed; and perform a first-stage reset of a first set of internal memory device subsystems based on the one or more reset levels.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

FIG. 2 is a diagram illustrating another example system 200 capable of implementing internal error correction sequences for a memory device. The system 200 may include one or more devices, apparatuses, and/or components for performing operations described herein. In some examples, the system 200 may be associated with a CXL protocol (e.g., the system 200 may utilize a CXL protocol to communicate between a host device, sometimes referred to as a CXL host, and a memory device, sometimes referred to as a CXL device) and/or may be a CXL compliant system. In that regard, the system 200 may include a CXL host 202 (which may correspond to the host system 105) and a CXL device 204 (e.g., a CXL compliant memory system, which may correspond to the memory system 110). The CXL host 202 and the CXL device 204 may communicate via an interface 203 (e.g., host interface 140), which may include a system management (SM) bus 206 and/or a CXL bus 208 (e.g., a PCIe/CXL interface), among other examples.

In some examples, the CXL device 204 may be a CXL compliant memory system (sometimes referred to herein as a CXL memory system, a CXL memory device, a CXL memory module, and/or a similar term). CXL is a high-speed CPU-to-device and CPU-to-memory interconnect designed to accelerate next-generation performance. CXL technology maintains memory coherency between the CPU memory space and memory on attached devices, which allows resource sharing for higher performance, reduced software stack complexity, and lower overall system cost. CXL is designed to be an industry open standard interface for high-speed communications. CXL technology is built on the PCIe infrastructure, leveraging PCIe physical and electrical interfaces to provide an advanced protocol in areas such as input/output (I/O) protocol, memory protocol, and coherency interface.

In some examples, the memory system 110 may include a PCIe/CXL interface (e.g., the CXL bus 208 may be associated with a PCIe/CXL interface), which may be a physical interface configured to connect the CXL device 204 to CXL compliant host devices, such as the CXL host 202. In such examples, the PCIe/CXL interface may comply with CXL standard specifications for physical connectivity, ensuring broad compatibility and ease of integration into existing systems using the CXL protocol. Additionally, or alternatively, the CXL device 204 may be designed to efficiently interface with computing systems (e.g., CXL host 202 and/or a host system 105) by leveraging the CXL protocol. For example, the CXL device 204 may be configured to utilize high-speed, low-latency interconnect capabilities of CXL, such as for a purpose of making the CXL device 204 suitable for high-performance computing, data center applications, artificial intelligence (AI) applications, and/or similar applications.

In some examples, the CXL device 204 may include a CXL memory controller (which may correspond to the memory system controller 115 and/or local controller 125), which may be configured to manage data flow between memory arrays (shown as CXL attached memory 218, which may correspond to the volatile memory arrays 135 and/or the memory arrays 130) and a CXL interface (e.g., the CXL bus 208). In some examples, the CXL memory controller may be configured to handle one or more CXL protocol layers, such as an I/O layer (e.g., a layer associated with a CXL.io protocol, which may be used for purposes such as device discovery, configuration, initialization, I/O virtualization, direct memory access (DMA) using non-coherent load-store semantics, and/or similar purposes); a cache coherency layer (e.g., a layer associated with a CXL.cache protocol, which may be used for purposes such as caching host memory using a modified, exclusive, shared, invalid (MESI) coherence protocol, or similar purposes); or a memory protocol layer (e.g., a layer associated with a CXL.memory (sometimes referred to as CXL.mem) protocol, which may enable a CXL memory device to expose host-managed device memory (HDM) to permit a host device to manage and access memory similar to a native DDR connected to the host); among other examples.

The CXL device 204 may further include and/or be associated with one or more high-bandwidth memory modules (HBMMs) or similar memory arrays (e.g., CXL attached memory 218). For example, the CXL device 204 may include multiple layers of DRAM (e.g., stacked and/or interconnected through advanced through-silicon via (TSV) technology) in order to maximize storage density and/or enhance data transfer speeds between memory layers. Additionally, or alternatively, the CXL device 204 may include a power management unit, which may be configured to regulate power consumption associated with the CXL device 204 and/or which may be configured to improve energy efficiency for the CXL device 204. Additionally, or alternatively, the CXL device 204 may include additional components, such as one or more error correction code (ECC) engines, such as for a purpose of detecting and/or correcting data errors to ensure data integrity and/or improve the overall reliability of the CXL device 204. The CXL device 204 may be implemented using a combination of hardware and firmware blocks and/or components. In such examples, the firmware may execute on one or more embedded CPUs within the CXL device 204.

Additionally, or alternatively, the CXL device 204 and/or a CXL controller (e.g., an ASIC) of the CXL device 204 may include CXL host interface hardware 210, an I/O path hardware logic and DMA controller 212, a main management subsystem 214, and/or a host interface (HIF) management subsystem 216, among other examples. In some examples, the CXL host interface hardware 210 may be hardware components that enable physical connectivity between the CXL device 204 and one or more external devices, such as to the CXL host 202 via the SM bus 206 and/or the CXL bus 208. In some examples, the CXL host interface hardware 210 may include the necessary physical interfaces and protocol logic required to establish and/or maintain communication over the CXL link (e.g., via the CXL bus 208). In some cases, the CXL host interface hardware 210 may ensure that the CXL host 202 can access and/or control the CXL device 204 efficiently.

The I/O path hardware logic and DMA controller 212 may handle data transfers between the CXL device 204 and external devices, such as other memory modules and/or peripheral components. In some examples, a DMA controller portion of the I/O path hardware logic and DMA controller 212 may permit efficient data transfer without involving a CXL device 204 CPU, directly. Put another way, the DMA controller portion of the I/O path hardware logic and DMA controller 212 may manage data movement between the CXL device 204 and other system components, which may enhance overall system performance by offloading data transfer tasks from the CPU.

The main management subsystem 214 may serve as a central control and management unit within the CXL device 204. In some examples, the main management subsystem 214 may encompass various functionalities and tasks, such as memory access control, error detection and/or correction, power management, and/or similar system management functionalities and/or tasks. Additionally, or alternatively, the main management subsystem 214 may ensure proper functioning and/or reliability of the CXL device 204 and/or may optimize a performance of the CXL device 204 under various operating conditions.

The HIF management subsystem 216 may be responsible for managing and/or controlling the CXL host interface hardware 210, among other tasks. In some examples, the HIF management subsystem 216 may handle tasks related to link initialization configuration negotiation with the CXL host 202, error handling, and/or other protocol-specific functionalities. Additionally, or alternatively, the HIF management subsystem 216 may ensure smooth communication between the CXL device 204 and/or the CXL host 202, such as by maintaining compatibility and/or reliability of the CXL link, among other examples.

In some examples, the CXL device 204 may be categorized as a CXL type 1 device, a CXL type 2 device, or a CXL type 3 device. A CXL type 1 device may be a device that implements a coherent cache using the CXL.cache protocol. A CXL type 2 device may be a device that implements both a coherent cache using the CXL.cache protocol and a host-managed device memory using the CXL.mem protocol. For example, a CXL type 2 device may be a hardware accelerator device. A CXL type 3 device may be a device that implements a host-managed device memory using the CXL.mem protocol. For example, a CXL type 3 device may be a memory expander device.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

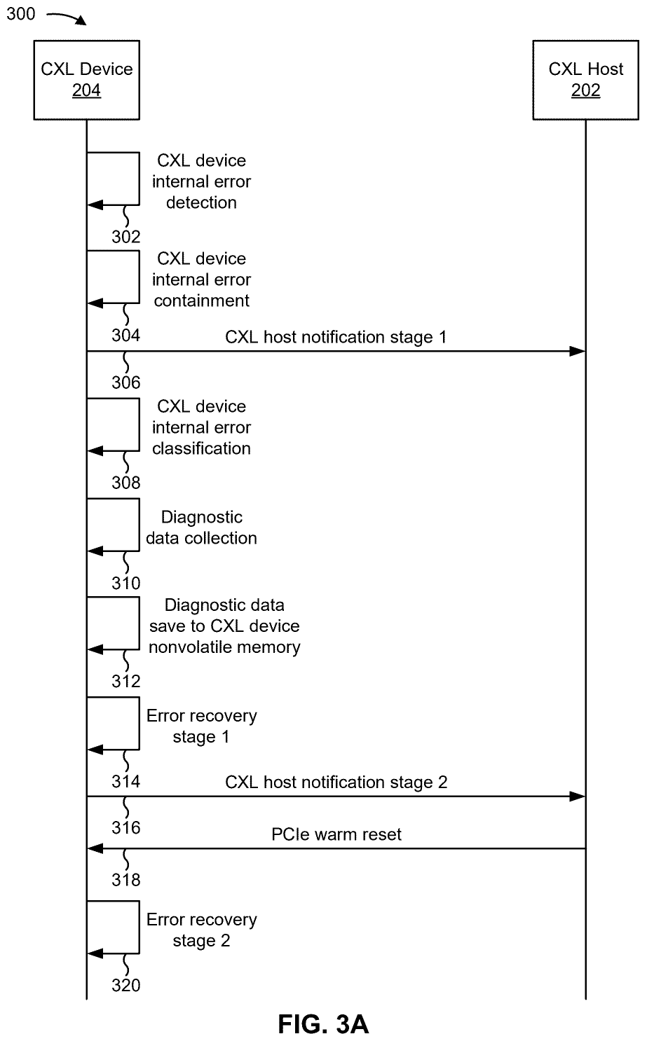

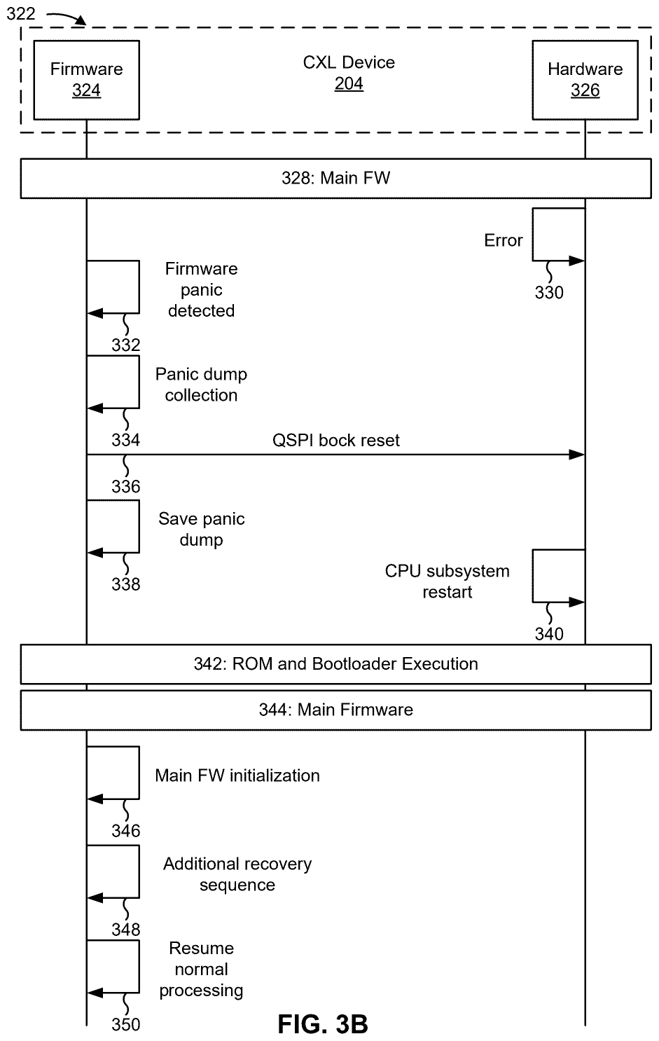

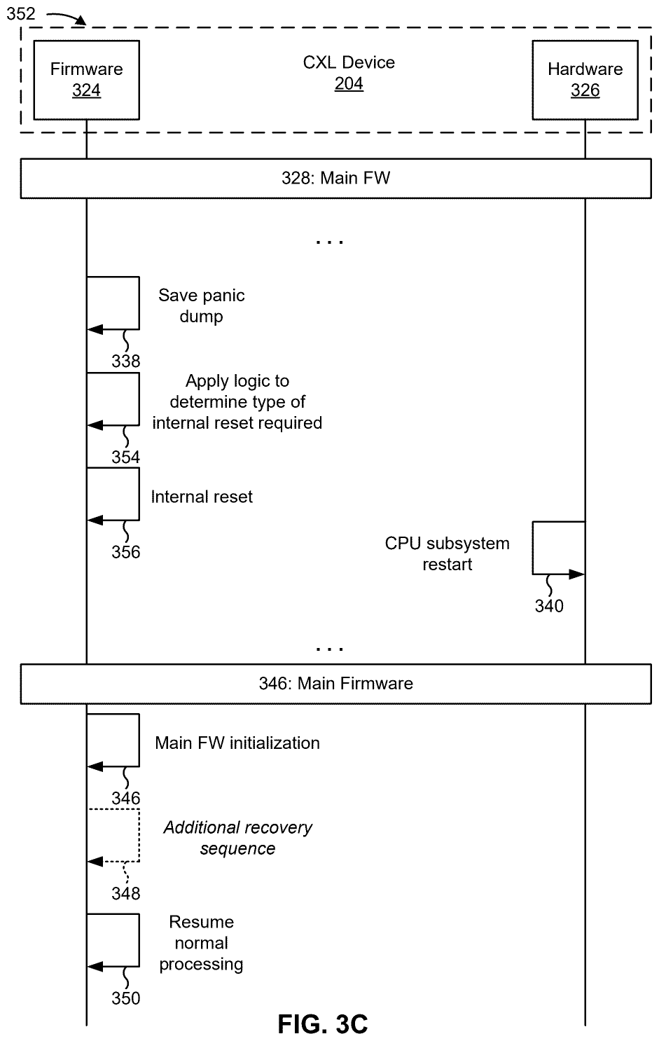

FIGS. 3A-3C are diagrams of examples associated with internal error correction sequences for a memory device. The operations described in connection with FIG. 3 may be performed by the memory system 110 and/or one or more components of the memory system 110, such as the memory system controller 115, one or more memory devices 120, and/or one or more local controllers 125, and/or by the CXL device 204 and/or one or more components of the CXL device 204, such as the I/O path hardware logic and DMA controller 212, the main management subsystem 214, and/or the HIF management subsystem 216.

In some implementations, a CXL device, such as the CXL device 204 described above in connection with FIG. 2, may be configured to implement an internal error correction sequence, such as a firmware panic sequence or a similar error correction sequence. As described above, “firmware panic sequence” may refer to a sequence that is initiated by internal device firmware (e.g., firmware running on an embedded CPU of the CXL device 204) when the firmware detects a firmware and/or hardware error which cannot be handled using the normal progression of the firmware. In such cases, the firmware may collect diagnostic data (e.g., a panic dump) and save the diagnostic data to nonvolatile storage, and/or the firmware may trigger an internal reset to recover from the firmware and/or hardware error and thus continue a normal firmware execution sequence. For example, an error that may cause firmware of the CXL device 204 to initiate a firmware panic sequence may include a CPU memory bus transaction error (e.g., an error due to a CXL device 204 CPU attempting to load and/or store to invalid memory addresses and/or perform invalid memory address alignment), a CPU stack overflow, a CPU instruction memory multi-bit ECC error, a firmware assertion condition failure, a watchdog timeout due to a hardware or firmware state machine hang condition, and/or a similar error.

FIG. 3A shows an example 300 associated with a firmware panic sequence procedure that implements two notifications transmitted to a host device, among other features. For ease of discussion, the operations shown and described in connection with FIG. 3A involve operations and/or communications performed by the CXL device 204 and the CXL host 202. However, in some other implementations, other memory devices and/or host devices may perform substantially similar operations as described below in connection with FIG. 3A. For example, the operations shown and described in connection with FIG. 3A may be performed by the memory system 110 and/or the host system 105 described above in connection with FIG. 1, among other examples.

In some implementations, any data sent by the CXL device 204 to the CXL host 202 after a firmware panic has occurred and before an appropriate error recovery sequence has occurred may be invalid, depending on the error condition that caused the CXL device 204 firmware panic to be initiated. However, the internal error that caused the CXL device 204 to initiate the firmware panic sequence and/or firmware panic sequence itself may disrupt the current normal host execution sequence, and thus may need to be fixed and/or more gracefully handled in a future firmware version to prevent a normal host execution sequence from being disrupted. Accordingly, the CXL device 204 may collect and/or save internal device diagnostic data when a firmware panic occurs, such that the diagnostic data may be retrieved by the CXL host 202 (e.g., for offline analysis). In this regard, the CXL device 204 may implement a two-stage host notification during a firmware panic sequence, such as for purposes of avoiding silent user data corruption (e.g., to prioritize clearly marking any data sent back to the CXL host 202 after an internal error has occurred as invalid), allowing the CXL host 202 to continue to make forward progress and/or avoid an unrecoverable host error that may otherwise require a host cold reset (e.g., power cycling the CXL host 202), avoiding error cascading (e.g., cascading host command timeouts) that may otherwise make failure analysis more difficult, allowing the CXL device 204 to collect and/or save internal diagnostic data to nonvolatile media (e.g., byte-addressable nonvolatile memory, among other examples) for later retrieval and/or offline failure analysis, and/or allowing the CXL host 202 to take appropriate error containment and/or recovery steps.

More particularly, as indicated by reference number 302, the CXL device 204 may detect an internal error. That is, as part of a firmware panic sequence, the CXL device 204 firmware may perform a device internal error detection step, in which the firmware detects an internal error that requires an internal-device-level hardware or firmware reset to recover from. In such cases, the firmware may initiate a firmware panic sequence. For example, firmware running on the CXL device 204 may detect an internal fatal uncorrectable error (e.g., an internal error that requires an internal reset of at least one component of the CXL device 204), and thus the firmware may initiate a firmware panic sequence.

As indicated by reference number 304, the CXL device 204 may contain the internal error, such as by causing embedded CPUs within the CXL device 204 to transition to a firmware panic error handling routine, among other examples. That is, as part of a firmware panic sequence, the CXL device 204 firmware may perform a device firmware internal error containment step, in which the internal device firmware notifies firmware running on all embedded CPUs that the firmware panic sequence has been initiated. In some implementations, the embedded CPUs may thus switch to a firmware panic error handling routine, which may include switching to a dedicated CPU stack and/or using only limited hardware functionality throughout any remaining firmware panic steps, such as for a purpose of reducing a probability of encountering additional errors during the firmware panic sequence.

As indicated by reference number 306, the CXL device 204 may transmit, and the CXL host 202 may receive, a first-stage notification indicating that the CXL device 204 has encountered the internal error. That is, as part of a firmware panic sequence, the CXL device 204 firmware may perform a first stage host notification step. For example, the CXL device 204 may send an initial notification to the CXL host 202 that notifies the CXL host 202 that an internal device error has occurred. In such implementations, the first-stage host notification step may serve to indicate to the CXL host 202 that commands currently in progress within the CXL device 204 (sometimes referred to as in-flight commands) and/or new commands sent to the CXL device 204 may be completed with an error status and/or may return invalid data.

In some implementations, the CXL device 204 may transmit the first-stage notification using one or more flits transmitted by the CXL device 204 to the CXL host 202. For example, the CXL device 204 may enter a viral mode, such as a CXL viral mode defined by a CXL 2.0 specification. In such implementations, the CXL device 204 may set a viral status bit (sometimes referred to as a Viral_Status bit) in a designated vendor-specific extended capability (DVSEC) CXL status register, such as a bit located at an offset of OE hexadecimal in the DVSEC CXL status register. In some implementations, the CXL device 204 may set the viral status bit in the DVSEC CXL status register based on a viral enable bit (sometimes referred to as a Viral_Enable bit) being set in a DVSEC CXL control register.

Additionally, or alternatively, the CXL device 204 may transmit the first-stage notification, such as by a device link layer on a CXL port (e.g., a port associated with the CXL bus 208) forcing a cyclic redundancy check (CRC) error on a next outgoing flit and by asserting a viral bit in a subsequent retry-acknowledgement flit (sometimes referred to as a RETRY.ack flit), as defined in a CXL protocol. Put another way, in some implementations, the first-stage notification may be implemented by the CXL device 204 forcing a CRC check error on a flit (e.g., a next outgoing flit after setting the viral status bit) transmitted by the CXL device 204 to the CXL host 202 and/or the CXL device setting a viral bit in another flit (e.g., a RETRY.ack flit) transmitted by the CXL device 204 to the CXL host 202. This may alert the CXL host 202 that the CXL device 204 has entered the firmware panic sequence and thus a validity of subsequently transmitted data (e.g., flits) is not to be trusted, thereby avoiding silent data corruption, while permitting the CXL device 204 to continue to send transmissions during a diagnostic data collection stage, thereby avoiding repeated host command timeouts and thus cascading errors.

As indicated by reference number 308, the CXL device 204 may perform an internal error classification procedure. Put another way, as part of a firmware panic sequence, the CXL device 204 firmware may perform a device internal error classification step. For example, the CXL device 204 firmware may determine whether special error handling steps are needed, such as whether special error handling steps are required based on the internal error source. In some implementations, the CXL device 204 firmware may select one or more reset levels (e.g., one or more of a first reset level associated with resetting non-host-interface components of the CXL device 204, a second reset level associated with resetting host-interface components of the CXL device 204, and/or similar reset levels) to be used to correct the internal device error, which is described in more detail below in connection with FIG. 3C.

As indicated by reference number 310, the CXL device 204 may perform diagnostic data collection. That is, as part of a firmware panic sequence, the CXL device 204 firmware may perform a device internal diagnostic data collection step. For example, the CXL device 204 firmware, such as firmware running on multiple CPU cores, may coordinate to capture a snapshot of an internal device state at the time of the internal error and/or diagnostic data to enable offline error root cause analysis, such as diagnostic data associated with CPU core stack frames, CPU registers, hardware registers, internal device memory address ranges, and/or similar information. Additionally, or alternatively, as indicated by reference number 312, the CXL device 204 may save the diagnostic data to nonvolatile memory. Put another way, as part of a firmware panic sequence, the CXL device 204 firmware may perform a device internal diagnostic data save to device internal nonvolatile media step. For example, the CXL device 204 firmware may save diagnostic data to nonvolatile media for later retrieval, such that the diagnostic data may be stored even if the CXL device 204 encounters a power removal before the diagnostic data can be retrieved. In some implementations, the nonvolatile media may be associated with a byte-addressable nonvolatile memory, which is described in more detail below in connection with FIG. 3B.

As indicated by reference number 314, the CXL device 204 may perform a first-stage error recovery procedure. Put another way, as part of a firmware panic sequence, the CXL device 204 firmware may perform a first-stage device internal error recovery step. For example, the CXL device 204 firmware may initiate reset of internal device subsystems (e.g., internal device hardware subsystems) that are not needed to maintain the host interface link (e.g., a CXL link via the CXL bus 208) and/or to respond to any host commands. In some implementations, this may permit certain internal device subsystems to return to normal functionality.

As indicated by reference number 316, the CXL device 204 may transmit, and the CXL host 202 may receive a second-stage host notification. That is, as part of a firmware panic sequence, the CXL device 204 firmware may perform a second-stage host notification step. For example, the CXL device 204 may transmit a notification to CXL host 202 indicating that the host is to perform a device reset, such as for a purpose of clearing all internal device error status codes and/or returning the CXL device 204 to normal functionality. In some implementations, the second-stage notification may be implemented by the CXL device 204 asserting a warm reset status in a reset-needed field of a memory device status register (e.g., the second-stage notification may indicate that the CXL host 202 is to perform a memory device reset procedure by asserting a Warm Reset status using a Reset Needed field of a Memory Device Status register, as defined by the CXL 2.0 specification), such as for a purpose of notifying the CXL host 202 that a PCIe warm reset is needed to recover from the internal device viral error condition. Additionally, or alternatively, in some implementations the CXL device 204 may, as part of the second-stage notification operations, create a memory module fatal error event record (e.g., the CXL device 204 may create a Memory Module Fatal Error Event Record, as defined by the CXL 2.0 specification), set a bit (e.g., bit 3) in an event status register corresponding to the memory module fatal error event record, and/or transmit, to the CXL host 202, an event notification interrupt communication indicating that the memory module fatal error event record is available for the CXL host 202 to read.

As indicated by reference number 318, in response to receiving the second-stage notification, the CXL host 202 may perform a memory device reset procedure, such as a PCIe warm reset procedure. Additionally, or alternatively, as indicated by reference number 320, based on the CXL host performing the PCIe warm reset procedure and/or a similar memory device reset procedure, the CXL device 204 may perform a second-stage error recovery procedure. For example, in some implementations the CXL device 204 may reset internal device data-path hardware blocks. Additionally, or alternatively, the CXL device 204 may perform an internal device reset of any remaining device subsystems that were not previously reset, such as for a purpose of clearing all internal device error status codes and/or returning the device to normal functionality.

As described above in connection with reference number 312, in some implementations the CXL device 204 may save diagnostic data (e.g., a panic dump) to nonvolatile device memory. In some memory devices, a panic dump typically gets stored in page-addressable nonvolatile memory, such as NAND flash memory or similar memory. In such examples, the page-addressable nonvolatile memory may be a portion of memory that requires endurance management (e.g., techniques and strategies used to prolong the lifespan and reliability of the nonvolatile memory, such as employing wear leveling and/or implementing ECC algorithms, among other endurance management techniques). In some examples, endurance management may be provided by an FTL associated with the page-addressable nonvolatile memory. Accordingly, in order to store a panic dump in the nonvolatile memory, recovery of the FTL firmware may be necessary. This may include rebooting the memory device's CPUs. However, rebooting the CPUs may require bringing up firmware to be executed in the hardware which caused the firmware panic in the first place, leading to unreliable panic dump saving because the firmware may fail as the firmware tries to initialize hardware that is in a panic state.

Accordingly, in some implementations, the CXL device 204 may save the diagnostic data (e.g., a panic dump) to byte-addressable nonvolatile memory. Using byte-addressable nonvolatile memory as the storage location for a panic dump may remove a need to fix the FTL after the firmware panic has commenced. Accordingly, by removing the need to fix the FTL, the CXL device 204 may not need to reboot the embedded CPUs prior to saving the diagnostic data, thereby reducing the complexity of the panic dump sequence. As a result, saving the diagnostic data to byte addressable nonvolatile memory may result in more reliable firmware recovery processes and thus increased memory device reliability and efficiency.

FIG. 3B shows an example 322 of a sequence associated with saving diagnostic data to a byte-addressable nonvolatile memory storage component of the CXL device 204. Again, although for ease of description the operations described below in connection with FIG. 3B are described in the context of the CXL device 204, in some other implementations, substantially similar operations may be performed by a different device without departing from the scope of the disclosure, such as the memory system 110 and/or a component thereof.

As shown by example 322, the operations associated with a firmware panic sequence and/or a diagnostic data (e.g., panic dump) saving operation may be associated with both firmware 324 of the CXL device 204 and hardware 326 of the CXL device 204. First, as indicated by reference number 328, certain operations may be associated with a main firmware progression of the CXL device 204. More particularly, as indicated by reference number 330, the hardware 326 of the CXL device 204 may encounter an internal error (e.g., an internal error that requires an internal reset of at least one component of the CXL device 204), such as the internal error described above in connection with FIG. 3A. Accordingly, as indicated by reference number 332, the firmware 324 may detect the internal error and/or determine that a firmware panic sequence is to be performed, which may be substantially similar to one or more of the operations described above in connection with reference numbers 302-308 of FIG. 3A. In response, as indicated by reference number 334, the firmware 324 may collect diagnostic data associated with the internal error, which may be substantially similar to the operations described above in connection with reference number 310 of FIG. 3A.

As indicated by reference number 336, the firmware 324 may cause a quad serial peripheral interface (QSPI) component (sometimes referred to as a QSPI block) of the hardware 326 to be reset. The QSPI component may be a serial interface used by embedded systems (e.g., a controller, such as the main management subsystem 214) of the CXL device 204 to communicate with peripheral systems, such as nonvolatile memory (e.g., byte-addressable nonvolatile memory), of the CXL device 204. In some implementations, QSPI may be used by the controller of the CXL device 204 to communicate with serial NOR memory that permits individual bytes to be read and written to independently (e.g., the byte-addressable nonvolatile memory may be NOR memory). In some implementations, the QSPI component may be configured to read data from the byte-addressable nonvolatile memory, write data to the byte-addressable nonvolatile memory, perform translations of byte addresses used by the CXL host 202 and/or controller of the CXL device 204 into appropriate memory commands associated with the byte-addressable nonvolatile memory, and/or implement error detection mechanisms (e.g., ECC mechanisms) associated with the byte-addressable nonvolatile memory, among other examples. Accordingly, by resetting the QSPI block, the CXL device 204 may access the nonvolatile memory without requiring rebooting of embedded CPUs or the like, thereby simplifying the panic dump saving procedure and thus increasing the reliability of the diagnostic procedures associated with the CXL device 204.

More particularly, as indicated by reference number 338, following the reset of the QSPI component, the firmware 324 may save the diagnostic data (e.g., the panic dump) to the byte-addressable nonvolatile storage component. Moreover, as indicated by reference number 340, following saving of the diagnostic data, the hardware 326 may restart certain components and/or systems, such as by restarting a CPU subsystem associated with the hardware 326.

In this way, the CXL device 204 may save the diagnostic data before executing a ROM and/or bootloader associated with the internal reset procedure, and/or before reinitializing a main firmware associated with the internal reset procedure. For example, as indicated by reference number 342, the CXL device 204 may perform a ROM execution and/or a bootloader execution. Moreover, as indicated by reference number 344, the CXL device 204 may reinitialize the main firmware and resume normal firmware progression. More particularly, as indicated by reference number 346, the firmware 324 may initialize the main firmware associated with the CXL device 204. In examples in which the panic dump is saved to page-addressable nonvolatile memory, a memory device may reinitialize an FTL in connection with the operations described in connection with reference number 346. In such examples, only after the operations shown in connection with reference number 346 have been completed may the memory device save the panic dump to the nonvolatile memory, resulting in unreliable diagnostic procedures. In contrast, because in this implementation the diagnostic data is saved to byte-addressable nonvolatile storage, the panic dump has already been saved, as described above in connection with reference number 338, resulting in improved diagnostic procedures and thus improved memory device operations.

As indicated by reference number 348, the firmware 324 may perform any additional recovery sequences in order to return the CXL device 204 to normal working order. Accordingly, once the additional recovery sequences have been performed (if any), the firmware 324 may return to normal processing, as indicated by reference number 350.

As described above in connection with reference number 308, in some implementations the CXL device 204 firmware 324 may select one or more reset levels (e.g., one or more of a first reset level associated with resetting non-host-interface components of the CXL device 204, a second reset level associated with resetting host-interface components of the CXL device 204, and/or similar reset levels) to be used to correct the internal device error. Example 352 shown in FIG. 3C shows one implementation in which the CXL device 204 firmware 324 may select one or more reset levels to be used to correct the internal device error. The operations shown in connection with FIG. 3C may include some of the steps described above in connection with FIG. 3B, which are like-numbered in FIG. 3C and thus are not described again in detail for ease of description.

In some examples, the CXL device 204 may be coherent with the CXL host 202 and thus may be treated by the CXL host 202 like any other processor package. Accordingly, in some examples the CXL host 202 may have an expectation that, prior to a managed hot removal of the CXL device 204 and/or prior to a sudden removal of the CXL device 204, a notification is to be transmitted by the CXL device 204 to a fabric manager such that the removal of the CXL device 204 may be handled safely without making the CXL host 202 enter a panic mode and/or crash. Alternatively, in some examples, a fabric manager may not be implemented to manage the CXL device 204. For example, the CXL device 204 may be associated with an SLD or a dual-ported device for which a fabric manager is not needed, and thus no fabric manager may be implemented. In such cases, a sudden removal of the CXL device 204 may need to be avoided so that the CXL host 202 does not enter a panic mode and/or crash.

Accordingly, in some cases, an internal reset implemented by the CXL device 204 may be associated with one or more reset levels, of multiple potential reset levels, such as for a purpose of avoiding a sudden removal condition for certain internal reset procedures. For example, a first reset level may be associated with resetting non-host-interface components of the CXL device 204 (e.g., the first reset level may reset all ASIC blocks and/or the main management subsystem 214, except for the HIF management subsystem 216 and/or a host interface management block) and/or a second reset level may be associated with resetting a host interface component of the CXL device 204 (e.g., the second reset level may reset only the HIF management subsystem 216 and/or the host interface management block). In such examples, the firmware 324 logic may choose and/or apply the different levels of internal reset based on the type of internal error encountered and/or the specific architecture being employed. For example, if the detected failure that caused the firmware panic is not related to a host interface component, the CXL device 204 may use only the first level reset. Additionally, or alternatively, if the detected failure that caused the firmware panic is due to the host interface component and if a fabric manager is available (meaning a surprise link down (e.g., a termination of a link without first providing a notification to the CXL host 202) caused by internal reset can be managed safely by CXL host 202 and, more particularly, by a fabric manager associated with the CXL host 202), the CXL device 204 may use both the first level reset and the second level reset for panic recovery. Additionally, or alternatively, if the detected failure that caused the firmware panic is due to the host interface component and if the fabric manager is not available, the CXL device 204 may use the first level reset and thus wait for CXL host 202 to take a next action, thereby avoiding the sudden removal condition.

More particularly, as indicated by reference number 354, after the firmware 324 has saved the diagnostic data to nonvolatile memory (e.g., a byte-addressable nonvolatile storage component, as described above in connection with reference number 338), the firmware 324 may apply logic to determine a type of reset required by the CXL device 204. For example, the firmware 324 may determine a type of the internal reset that is to be performed, and/or may select one or more reset levels, of multiple potential reset levels, to be used for the internal reset based on determining the type of the internal reset that is to be performed.

For example, as described above, a first reset level, of the multiple potential reset levels, may be associated with resetting non-host-interface components of the CXL device 204, and/or a second reset level, of the multiple potential reset levels, may be associated with resetting a host interface component of the CXL device 204. In such implementations, the logic described above in connection with reference number 354 may include determining whether the internal error is associated with the host interface component and/or determining whether the CXL device 204 and/or the CXL host 202 is associated with a CXL fabric manager. If the internal error is not associated with the host interface component, the firmware 324 may select only the first reset level, thereby reducing resource consumption associated with the internal reset procedure and/or avoiding unnecessary host errors associated with the internal reset procedure. If the internal error is associated with the host interface component and if the CXL device 204 is not associated with the CXL fabric manager, the firmware 324 may select only the first reset level, and then the CXL device 204 may wait for the CXL host 202 to take some additional action to avoid a sudden removal event. Alternatively, if the internal error is associated with the host interface component but the CXL device 204 and/or the CXL host 202 is associated with the CXL fabric manager, the firmware 324 may select the first reset level and the second reset level, because in such cases the host interface component reset may be safely managed by the fabric manager.

Accordingly, as indicated by reference number 356, the firmware 324 may perform an internal reset of one or more internal memory device subsystems based on the selected one or more reset levels. The operations may then proceed in a like manner as described above in connection with FIG. 3B. In some implementations, certain of the operations described above in connection with FIG. 3B may be avoided, due to the selected internal reset levels to be implemented in the firmware panic sequence. For example, as described above in connection with reference number 348, following a ROM and/or bootloader execution and an initialization of the main firmware, the firmware 324 may perform an additional recovery sequence. In some implementations, the additional recovery sequence may be associated with resetting a host interface component of the CXL device 204. In such implementations, the operations described above in connection with reference number 348 may be avoided (shown in FIG. 3C by using broken lines), such as when the host interface component is not to be reset. For example, in implementations in which the firmware 324 determines that only the first level reset is to be performed (e.g., resetting all ASIC blocks and/or the main management subsystem 214, except for the HIF management subsystem 216 and/or a host interface management block), the additional recovery sequence shown in connection with reference number 348 may be avoided altogether, thereby reducing resource consumption associated with the firmware panic sequence.

As indicated above, FIGS. 3A-3C are provided as examples. Other examples may differ from what is described with regard to FIGS. 3A-3C.

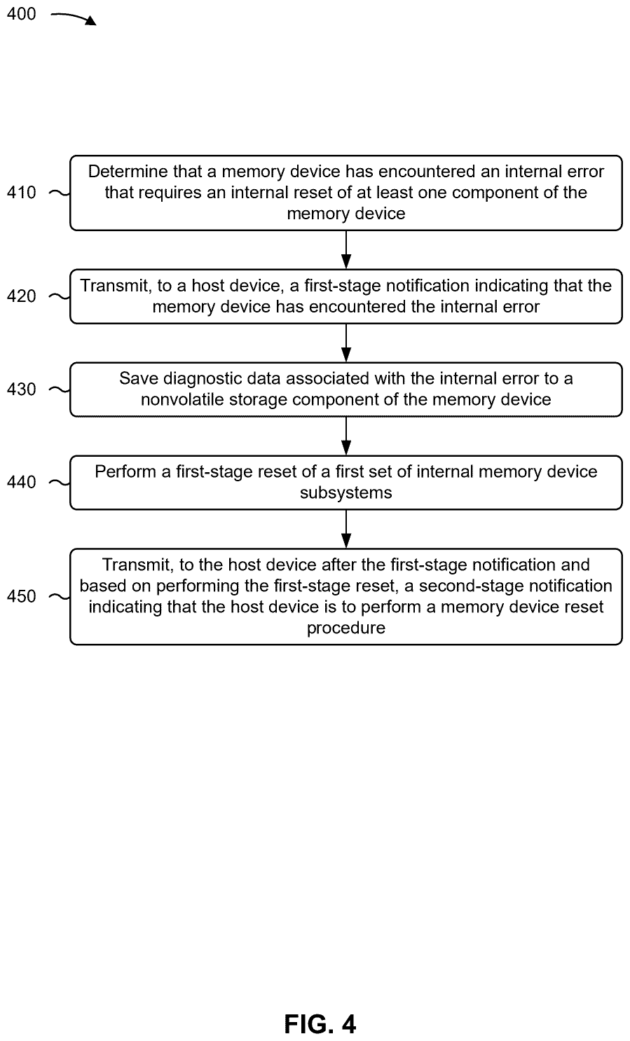

FIG. 4 is a flowchart of an example method 400 associated with internal error correction sequences for a memory device. In some implementations, a memory device and/or memory system (e.g., the memory system 110, the memory device 120, and/or the CXL device 204) may perform or may be configured to perform the method 400. In some implementations, another device or a group of devices separate from or including the memory device and/or the memory system (e.g., the system 100 and/or the system 200) may perform or may be configured to perform the method 400. Additionally, or alternatively, one or more components of the memory device and/or the memory system (e.g., the memory system controller 115, the local controller 125, the I/O path hardware logic and DMA controller 212, the main management subsystem 214, and/or the HIF management subsystem 216) may perform or may be configured to perform the method 400. Thus, means for performing the method 400 may include the memory device and/or the memory system, and/or one or more components of the memory device and/or the memory system. Additionally, or alternatively, a non-transitory computer-readable medium may store one or more instructions that, when executed by the memory device and/or the memory system, cause the memory device and/or the memory system to perform the method 400.

As shown in FIG. 4, the method 400 may include determining that the memory device has encountered an internal error that requires an internal reset of at least one component of the memory device (block 410). For example, the CXL device 204 (e.g., firmware 324 of the CXL device 204) may determine that the CXL device 204 has encountered an internal error (e.g., the hardware error described above in connection with reference number 330) that requires an internal reset, as described above in connection with reference numbers 302 and 332. As further shown in FIG. 4, the method 400 may include transmitting, to a host device, a first-stage notification indicating that the memory device has encountered the internal error (block 420). For example, the CXL device 204 may transmit to the CXL host 202 the first-stage notification described above in connection with reference number 306.

As further shown in FIG. 4, the method 400 may include saving diagnostic data associated with the internal error to a nonvolatile storage component of the memory device (block 430). For example, the CXL device 204 may save a panic dump to nonvolatile memory, as described above in connection with reference numbers 312 and 338. As further shown in FIG. 4, the method 400 may include performing a first-stage reset of a first set of internal memory device subsystems (block 440). For example, the CXL device 204 may perform the first-stage reset described above in connection with reference number 314 and/or may cause the hardware 326 CPU subsystem restart, as described above in connection with reference number 340. As further shown in FIG. 4, the method 400 may include transmitting, to the host device after the first-stage notification and based on performing the first-stage reset, a second-stage notification indicating that the host device is to perform a memory device reset procedure (block 450). For example, the CXL device 204 may transmit to the CXL host 202 the second-stage notification described above in connection with reference number 316.

The method 400 may include additional aspects, such as any single aspect or any combination of aspects described below and/or described in connection with one or more other methods or operations described elsewhere herein.

In a first aspect, the method 400 may include setting a viral status bit in a DVSEC CXL status register, and transmitting the first-stage notification may include transmitting the first-stage notification in response to setting the viral status bit in the DVSEC CXL status register. For example, the CXL device 204 may set the viral status bit in the DVSEC CXL status register, as described above in connection with reference number 306.

In a second aspect, alone or in combination with the first aspect, transmitting the first-stage notification may include forcing a cyclic redundancy check error on a first flit transmitted by the memory device to the host device and setting a viral bit in a second flit transmitted by the memory device to the host device. For example, the CXL device 204 may force a CRC error on a next outgoing flit in response to initiating a firmware panic sequence and the CXL device 204 may set a viral bit in a RETRY.ack flit, as described above in connection with reference number 306.

In a third aspect, alone or in combination with one or more of the first and second aspects, the second-stage notification indicates that the host device is to perform the memory device reset procedure using a reset-needed field of a memory device status register. For example, the CXL device 204 may indicate to the CXL host 202 that the CXL host 202 is to perform the memory device reset procedure using a reset-needed field of a memory device status register, as described above in connection with reference number 316.

In a fourth aspect, alone or in combination with one or more of the first through third aspects, transmitting the second-stage notification includes creating a memory module fatal error event record, setting a bit in an event status register corresponding to the memory module fatal error event record, and transmitting, to the host device, an event notification interrupt communication indicating that the memory module fatal error event record is available. For example, the CXL device 204 may create a memory module fatal error event record, may set a bit in an event status register corresponding to the memory module fatal error event record, and/or may transmit, to the CXL host 202, an event notification interrupt communication indicating that the memory module fatal error event record is available, as described above in connection with reference number 306.

In a fifth aspect, alone or in combination with one or more of the first through fourth aspects, the method 400 includes performing, with the host device, a reset of a host interface, and performing, based on resetting the host interface, a second-stage reset of a second set of internal memory device subsystems. For example, the CXL device 204 may perform, with the CXL host 202, the PCIe warm reset procedure described above in connection with reference number 318, and/or the CXL device may perform the second-stage error recovery procedure described above in connection with reference numbers 320 and 348.

In a sixth aspect, alone or in combination with one or more of the first through fifth aspects, the nonvolatile storage component is a byte-addressable nonvolatile storage component. For example, the CXL device 204 may save the diagnostic data to byte-addressable nonvolatile memory (e.g., NOR memory), as described above in connection with example 322 of FIG. 3B.

In a seventh aspect, alone or in combination with one or more of the first through sixth aspects, the method 400 includes resetting a QSPI component associated with the memory device, and saving the diagnostic data to the byte-addressable nonvolatile storage component based on resetting the QSPI component. For example, the CXL device 204 may reset the QSPI block, as described above in connection with reference number 336, and/or the CXL device 204 may save the panic dump to the byte-addressable nonvolatile (e.g., NOR memory) after resetting the QSPI block, as described above in connection with reference number 338.

In an eighth aspect, alone or in combination with one or more of the first through seventh aspects, the method 400 includes determining a type of the internal reset that is to be performed, and selecting one or more reset levels, of multiple potential reset levels, to be used for the internal reset based on determining the type of the internal reset that is to be performed. For example, as described above in connection with reference number 354, the CXL device 204 may apply logic to determine if a first reset level (e.g., a reset level associated with resetting non-host-interface components of the CXL device 204) and/or a second reset level (e.g., a reset level associated with resetting a host interface component of the CXL device 204) is to be performed, such as by determining whether the internal error is associated with the host interface.

In a ninth aspect, alone or in combination with one or more of the first through eighth aspects, a first reset level, of the multiple potential reset levels, is associated with resetting non-host-interface components of the memory device, and a second reset level, of the multiple potential reset levels, is associated with resetting a host interface component of the memory device. For example, the CXL device 204 may apply the logic described above in connection with reference number 354.

In a tenth aspect, alone or in combination with one or more of the first through ninth aspects, the method 400 includes determining whether the internal error is associated with the host interface component, determining whether the memory device is associated with a fabric manager, and performing one of selecting only the first reset level based on determining that the internal error is not associated with the host interface component, selecting only the first reset level based on determining that the internal error is associated with the host interface component and that the memory device is not associated with the fabric manager, or selecting the first reset level and the second reset level based on determining that the internal error is associated with the host interface component and that the memory device is associated with the fabric manager. For example, the CXL device 204 may select the first reset level based on determining that the internal error is not associated with the host interface component, may select only the first reset level based on determining that the internal error is associated with the host interface component and that the CXL device 204 and/or the CXL host 202 is not associated with a CXL fabric manager, or may select the first reset level and the second reset level based on determining that the internal error is associated with the host interface component and that the CXL device 204 and/or the CXL host 202 is associated with the CXL fabric manager.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

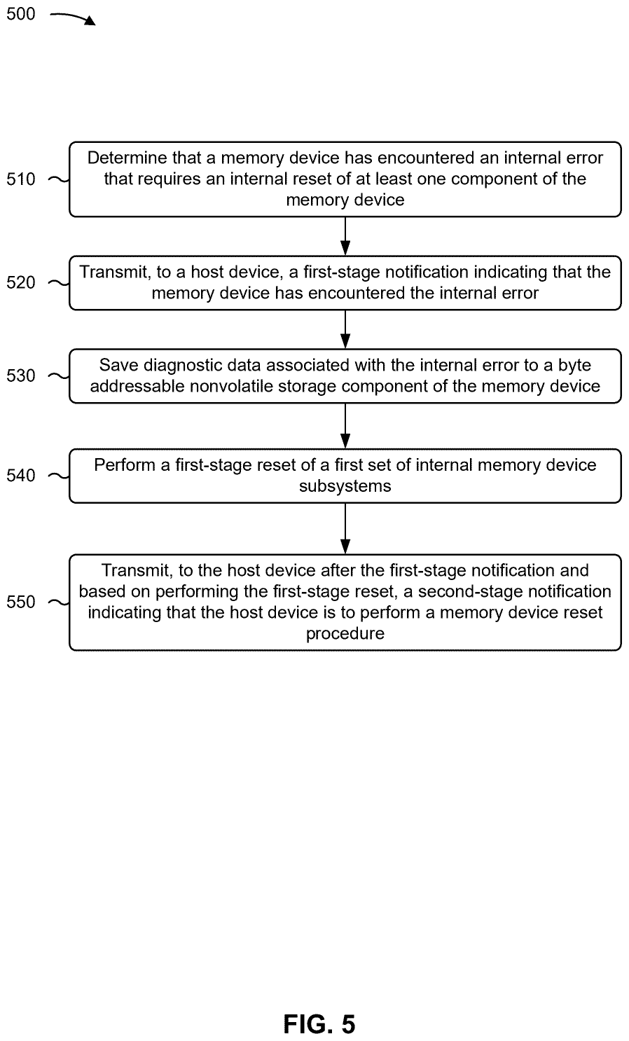

FIG. 5 is a flowchart of another example method 500 associated with internal error correction sequences for a memory device. In some implementations, a memory device and/or memory system (e.g., the memory system 110, the memory device 120, and/or the CXL device 204) may perform or may be configured to perform the method 500. In some implementations, another device or a group of devices separate from or including the memory device and/or the memory system (e.g., the system 100 and/or the system 200) may perform or may be configured to perform the method 500.

Additionally, or alternatively, one or more components of the memory device and/or the memory system (e.g., the memory system controller 115, the local controller 125, the I/O path hardware logic and DMA controller 212, the main management subsystem 214, and/or the HIF management subsystem 216) may perform or may be configured to perform the method 500. Thus, means for performing the method 500 may include the memory device and/or the memory system, and/or one or more components of the memory device and/or the memory system. Additionally, or alternatively, a non-transitory computer-readable medium may store one or more instructions that, when executed by the memory device and/or the memory system, cause the memory device and/or the memory system to perform the method 500.

As shown in FIG. 5, the method 500 may include determining that the memory device has encountered an internal error that requires an internal reset of at least one component of the memory device (block 510). For example, the CXL device 204 (e.g., firmware 324 of the CXL device 204) may determine that the CXL device 204 has encountered an internal error (e.g., the hardware error described above in connection with reference number 330) that requires an internal reset, as described above in connection with reference numbers 302 and 332. As further shown in FIG. 5, the method 500 may include transmitting a first-stage notification indicating that the memory device has encountered the internal error (block 520). For example, the CXL device 204 may transmit to the CXL host 202 the first-stage notification described above in connection with reference number 306.

As further shown in FIG. 5, the method 500 may include saving diagnostic data associated with the internal error to a byte-addressable nonvolatile storage component of the memory device (block 530). For example, the CXL device 204 may save the diagnostic data to byte-addressable nonvolatile memory (e.g., NOR memory), as described above in connection with example 322 of FIG. 3B. As further shown in FIG. 5, the method 500 may include performing a first-stage reset of a first set of internal memory device subsystems (block 540). For example, the CXL device 204 may perform the first-stage reset described above in connection with reference number 314 and/or may cause the hardware 326 CPU subsystem restart, as described above in connection with reference number 340. As further shown in FIG. 5, the method 500 may include transmitting, by the memory device to the host device after the first-stage notification and based on performing the first-stage reset, a second-stage notification indicating that the host device is to perform a memory device reset procedure (block 550). For example, the CXL device 204 may transmit to the CXL host 202 the second-stage notification described above in connection with reference number 316.

The method 500 may include additional aspects, such as any single aspect or any combination of aspects described below and/or described in connection with one or more other methods or operations described elsewhere herein.

In a first aspect, the method 500 includes setting, by the memory device, a viral status bit in a DVSEC CXL status register, wherein transmitting the first-stage notification includes transmitting the first-stage notification in response to setting the viral status bit in the DVSEC CXL status register. For example, the CXL device 204 may set the viral status bit in the DVSEC CXL status register, as described above in connection with reference number 306.

In a second aspect, alone or in combination with the first aspect, transmitting the first-stage notification includes forcing a cyclic redundancy check error on a first flit transmitted by the memory device to the host device, and setting a viral bit in a second flit transmitted by the memory device to the host device. For example, the CXL device 204 may force a CRC error on a next outgoing flit in response to initiating a firmware panic sequence and the CXL device 204 may set a viral bit in a RETRY.ack flit, as described above in connection with reference number 306.

In a third aspect, alone or in combination with one or more of the first through second aspects, the second-stage notification indicates that the host device is to perform the memory device reset procedure using a reset-needed field of a memory device status register. For example, the CXL device 204 may indicate to the CXL host 202 that the CXL host 202 is to perform the memory device reset procedure using a reset-needed field of a memory device status register, as described above in connection with reference number 316.

In a fourth aspect, alone or in combination with one or more of the first through third aspects, transmitting the second-stage notification includes creating, by the memory device, a memory module fatal error event record, setting, by the memory device, a bit in an event status register corresponding to the memory module fatal error event record, and transmitting, by the memory device to the host device, an event notification interrupt communication indicating that the memory module fatal error event record is available. For example, the CXL device 204 may create a memory module fatal error event record, may set a bit in an event status register corresponding to the memory module fatal error event record, and/or may transmit, to the CXL host 202, an event notification interrupt communication indicating that the memory module fatal error event record is available, as described above in connection with reference number 306.

In a fifth aspect, alone or in combination with one or more of the first through fourth aspects, the method 500 includes performing, by the memory device with the host device, a reset of a host interface, and performing, by the memory device and based on resetting the host interface, a second-stage reset of a second set of internal memory device subsystems. For example, the CXL device 204 may perform, with the CXL host 202, the PCIe warm reset procedure described above in connection with reference number 318, and/or the CXL device may perform the second-stage error recovery procedure described above in connection with reference numbers 320 and 348.

In a sixth aspect, alone or in combination with one or more of the first through fifth aspects, the method 500 includes resetting, by the memory device, a QSPI component associated with the memory device, and saving, by the memory device, the diagnostic data to the byte-addressable nonvolatile storage component based on resetting the QSPI component. For example, the CXL device 204 may reset the QSPI block, as described above in connection with reference number 336, and/or the CXL device 204 may save the panic dump to the byte-addressable nonvolatile (e.g., NOR memory) after resetting the QSPI block, as described above in connection with reference number 338.

In a seventh aspect, alone or in combination with one or more of the first through sixth aspects, the method 500 includes determining, by the memory device, a type of the internal reset that is to be performed, and selecting, by the memory device, one or more reset levels, of multiple potential reset levels, to be used for the internal reset based on determining the type of the internal reset that is to be performed. For example, as described above in connection with reference number 354, the CXL device 204 may apply logic to determine if a first reset level (e.g., a reset level associated with resetting non-host-interface components of the CXL device 204) and/or a second reset level (e.g., a reset level associated with resetting a host interface component of the CXL device 204) is to be performed, such as by determining whether the internal error is associated with the host interface.

In an eighth aspect, alone or in combination with one or more of the first through seventh aspects, a first reset level, of the multiple potential reset levels, is associated with resetting non-host-interface components of the memory device, and a second reset level, of the multiple potential reset levels, is associated with resetting a host interface component of the memory device. For example, the CXL device 204 may apply the logic described above in connection with reference number 354.

In a ninth aspect, alone or in combination with one or more of the first through eighth aspects, the method 500 includes determining, by the memory device, whether the internal error is associated with the host interface component, determining, by the memory device, whether the memory device is associated with a fabric manager, and performing, by the memory device, one of selecting only the first reset level based on determining that the internal error is not associated with the host interface component, selecting only the first reset level based on determining that the internal error is associated with the host interface component and that the memory device is not associated with the fabric manager, or selecting the first reset level and the second reset level based on determining that the internal error is associated with the host interface component and that the memory device is associated with the fabric manager. For example, the CXL device 204 may select the first reset level based on determining that the internal error is not associated with the host interface component, may select only the first reset level based on determining that the internal error is associated with the host interface component and that the CXL device 204 and/or the CXL host 202 is not associated with a CXL fabric manager, or may select the first reset level and the second reset level based on determining that the internal error is associated with the host interface component and that the CXL device 204 and/or the CXL host 202 is associated with the CXL fabric manager.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

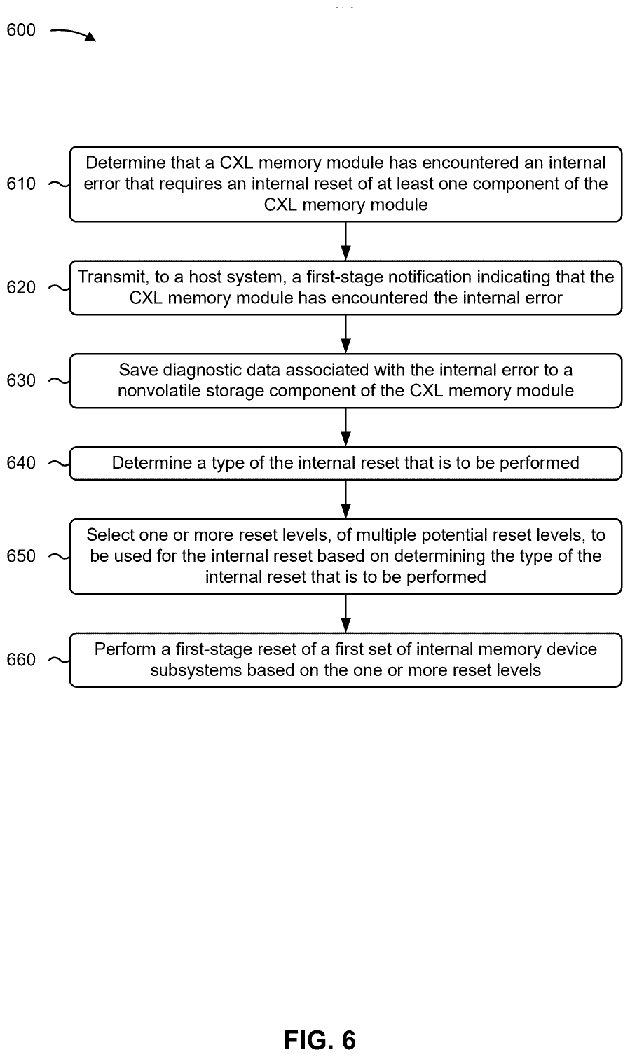

FIG. 6 is a flowchart of another example method 600 associated with internal error correction sequences for a memory device. In some implementations, a memory device and/or memory system (e.g., the memory system 110, the memory device 120, and/or the CXL device 204) may perform or may be configured to perform the method 600. In some implementations, another device or a group of devices separate from or including the memory device and/or the memory system (e.g., the system 100 and/or the system 200) may perform or may be configured to perform the method 600.

Additionally, or alternatively, one or more components of the memory device and/or the memory system (e.g., the memory system controller 115, the local controller 125, the I/O path hardware logic and DMA controller 212, the main management subsystem 214, and/or the HIF management subsystem 216) may perform or may be configured to perform the method 600. Thus, means for performing the method 600 may include the memory device and/or the memory system, and/or one or more components of the memory device and/or the memory system. Additionally, or alternatively, a non-transitory computer-readable medium may store one or more instructions that, when executed by the memory device and/or the memory system, cause the memory device and/or the memory system to perform the method 600.

As shown in FIG. 6, the method 600 may include determining that a CXL memory module has encountered an internal error that requires an internal reset of at least one component of the CXL memory module (block 610). For example, the CXL device 204 (e.g., firmware 324 of the CXL device 204) may determine that the CXL device 204 has encountered an internal error (e.g., the hardware error described above in connection with reference number 330) that requires an internal reset, as described above in connection with reference numbers 302 and 332. As further shown in FIG. 6, the method 600 may include transmitting, to a host system, a first-stage notification indicating that the CXL memory module has encountered the internal error (block 620). For example, the CXL device 204 may transmit to the CXL host 202 the first-stage notification described above in connection with reference number 306.

As further shown in FIG. 6, the method 600 may include saving diagnostic data associated with the internal error to a nonvolatile storage component of the CXL memory module (block 630). For example, the CXL device 204 may save a panic dump to nonvolatile memory, as described above in connection with reference numbers 312 and 338. As further shown in FIG. 6, the method 600 may include determining a type of the internal reset that is to be performed (block 640). For example, the CXL device 204 may determine if the internal reset is associated with resetting non-host-interface components of the CXL device 204 and/or is associated with resetting a host interface component of the CXL device 204, as described above in connection with reference number 354. As further shown in FIG. 6, the method 600 may include selecting one or more reset levels, of multiple potential reset levels, to be used for the internal reset based on determining the type of the internal reset that is to be performed (block 650). For example, as described above in connection with reference number 354, the CXL device 204 may apply logic to determine if a first reset level (e.g., a reset level associated with resetting non-host-interface components of the CXL device 204) and/or a second reset level (e.g., a reset level associated with resetting a host interface component of the CXL device 204) is to be performed. As further shown in FIG. 6, the method 600 may include performing a first-stage reset of a first set of internal memory device subsystems based on the one or more reset levels (block 660). For example, the CXL device 204 may perform the first-stage reset described above in connection with reference number 314 and/or may cause the hardware 326 CPU subsystem restart, as described above in connection with reference number 340.

The method 600 may include additional aspects, such as any single aspect or any combination of aspects described below and/or described in connection with one or more other methods or operations described elsewhere herein.

In a first aspect, the method 600 may include setting a viral status bit in a DVSEC CXL status register, wherein transmitting the first-stage notification includes transmitting the first-stage notification in response to setting the viral status bit in the DVSEC CXL status register. For example, the CXL device 204 may set the viral status bit in the DVSEC CXL status register, as described above in connection with reference number 306.

In a second aspect, alone or in combination with the first aspect, transmitting the first-stage notification may include forcing a cyclic redundancy check error on a first flit transmitted by the CXL memory module to the host system and setting a viral bit in a second flit transmitted by the CXL memory module to the host system. For example, the CXL device 204 may force a CRC error on a next outgoing flit in response to initiating a firmware panic sequence and the CXL device 204 may set a viral bit in a RETRY.ack flit, as described above in connection with reference number 306.

In a third aspect, alone or in combination with one or more of the first and second aspects, the method 600 may include transmitting, to the host system after the first-stage notification and based on performing the first-stage reset, a second-stage notification indicating that the host system is to perform a memory module reset procedure. For example, the CXL device 204 may transmit to the CXL host 202 the second-stage notification described above in connection with reference number 316.

In a fourth aspect, alone or in combination with one or more of the first through third aspects, the second-stage notification indicates that the host system is to perform the memory module reset procedure using a reset-needed field of a CXL memory module status register. For example, the CXL device 204 may indicate to the CXL host 202 that the CXL host 202 is to perform the memory device reset procedure using a reset-needed field of a memory device status register, as described above in connection with reference number 316.

In a fifth aspect, alone or in combination with one or more of the first through fourth aspects, transmitting the second-stage notification includes creating a memory module fatal error event record, setting a bit in an event status register corresponding to the memory module fatal error event record, and transmitting, to the host system, an event notification interrupt communication indicating that the memory module fatal error event record is available. For example, the CXL device 204 may create a memory module fatal error event record, may set a bit in an event status register corresponding to the memory module fatal error event record, and/or may transmit, to the CXL host 202, an event notification interrupt communication indicating that the memory module fatal error event record is available, as described above in connection with reference number 306.

In a sixth aspect, alone or in combination with one or more of the first through fifth aspects, the method 600 includes performing, with the host system, a reset of a host interface, and performing, based on resetting the host interface, a second-stage reset of a second set of internal memory device subsystems. For example, the CXL device 204 may perform, with the CXL host 202, the PCIe warm reset procedure described above in connection with reference number 318, and/or the CXL device may perform the second-stage error recovery procedure described above in connection with reference numbers 320 and 348.

In a seventh aspect, alone or in combination with one or more of the first through sixth aspects, the nonvolatile storage component is a byte-addressable nonvolatile storage component. For example, the CXL device 204 may save the diagnostic data to byte-addressable nonvolatile memory (e.g., NOR memory), as described above in connection with example 322 of FIG. 3B.

In an eighth aspect, alone or in combination with one or more of the first through seventh aspects, the method 600 includes resetting a QSPI component associated with the CXL memory module, and saving the diagnostic data to the byte-addressable nonvolatile storage component based on resetting the QSPI component. For example, the CXL device 204 may reset the QSPI block, as described above in connection with reference number 336, and/or the CXL device 204 may save the panic dump to the byte-addressable nonvolatile (e.g., NOR memory) after resetting the QSPI block, as described above in connection with reference number 338.

In a ninth aspect, alone or in combination with one or more of the first through eighth aspects, a first reset level, of the multiple potential reset levels, is associated with resetting non-host-interface components of the CXL memory module, and a second reset level, of the multiple potential reset levels, is associated with resetting a host interface component of the CXL memory module. For example, the CXL device 204 may apply the logic described above in connection with reference number 354.

In a tenth aspect, alone or in combination with one or more of the first through ninth aspects, the method 600 includes determining whether the internal error is associated with the host interface component, determining whether the CXL memory module is associated with a CXL fabric manager, and performing one of selecting only the first reset level based on determining that the internal error is not associated with the host interface component, selecting only the first reset level based on determining that the internal error is associated with the host interface component and that the CXL memory module is not associated with the CXL fabric manager, or selecting the first reset level and the second reset level based on determining that the internal error is associated with the host interface component and that the CXL memory module is associated with the CXL fabric manager. For example, the CXL device 204 may select the first reset level based on determining that the internal error is not associated with the host interface component, may select only the first reset level based on determining that the internal error is associated with the host interface component and that the CXL device 204 and/or the CXL host 202 is not associated with a CXL fabric manager, or may select the first reset level and the second reset level based on determining that the internal error is associated with the host interface component and that the CXL device 204 and/or the CXL host 202 is associated with the CXL fabric manager.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory device includes one or more components configured to: determine that the memory device has encountered an internal error that requires an internal reset of at least one component of the memory device; transmit, to a host device, a first-stage notification indicating that the memory device has encountered the internal error; save diagnostic data associated with the internal error to a nonvolatile storage component of the memory device; perform a first-stage reset of a first set of internal memory device subsystems; and transmit, to the host device after the first-stage notification and based on performing the first-stage reset, a second-stage notification indicating that the host device is to perform a memory device reset procedure.

In some implementations, a method includes determining, by a memory device, that the memory device has encountered an internal error that requires an internal reset of at least one component of the memory device; transmitting, by the memory device to a host device, a first-stage notification indicating that the memory device has encountered the internal error; saving, by the memory device, diagnostic data associated with the internal error to a byte-addressable nonvolatile storage component of the memory device; performing a first-stage reset of a first set of internal memory device subsystems; and transmitting, by the memory device to the host device after the first-stage notification and based on performing the first-stage reset, a second-stage notification indicating that the host device is to perform a memory device reset procedure.

In some implementations, a compute express link (CXL) memory module includes one or more components configured to: determine that the CXL memory module has encountered an internal error that requires an internal reset of at least one component of the CXL memory module; transmit, to a host system, a first-stage notification indicating that the CXL memory module has encountered the internal error; save diagnostic data associated with the internal error to a nonvolatile storage component of the CXL memory module; determine a type of the internal reset that is to be performed; select one or more reset levels, of multiple potential reset levels, to be used for the internal reset based on determining the type of the internal reset that is to be performed; and perform a first-stage reset of a first set of internal memory device subsystems based on the one or more reset levels.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
determine that the memory device has encountered an internal error that requires an internal reset of at least one component of the memory device;
transmit, to a host device, a first-stage notification indicating that the memory device has encountered the internal error;
save diagnostic data associated with the internal error to a nonvolatile storage component of the memory device;
perform a first-stage reset of a first set of internal memory device subsystems; and
transmit, to the host device after the first-stage notification and based on performing the first-stage reset, a second-stage notification indicating that the host device is to perform a memory device reset procedure.

2. The memory device of claim 1, wherein the one or more components are further configured to set a viral status bit in a designated vendor-specific extended capability (DVSEC) compute express link (CXL) status register,
wherein the one or more components, to transmit the first-stage notification, are configured to transmit the first-stage notification in response to setting the viral status bit in the DVSEC CXL status register.

3. The memory device of claim 1, wherein the one or more components, to transmit the first-stage notification, are configured to:
force a cyclic redundancy check error on a first flit transmitted by the memory device to the host device, and
set a viral bit in a second flit transmitted by the memory device to the host device.

4. The memory device of claim 1, wherein the second-stage notification indicates that the host device is to perform the memory device reset procedure using a reset-needed field of a memory device status register.

5. The memory device of claim 1, wherein the one or more components, to transmit the second-stage notification, are configured to:
create a memory module fatal error event record;
set a bit in an event status register corresponding to the memory module fatal error event record; and
transmit, to the host device, an event notification interrupt communication indicating that the memory module fatal error event record is available.

6. The memory device of claim 1, wherein the one or more components are further configured to:
perform, with the host device, a reset of a host interface; and
perform, based on resetting the host interface, a second-stage reset of a second set of internal memory device subsystems.

7. The memory device of claim 1, wherein the nonvolatile storage component is a byte-addressable nonvolatile storage component.

8. The memory device of claim 7, wherein the one or more components are further configured to:
reset a quad serial peripheral interface (QSPI) component associated with the memory device; and
save the diagnostic data to the byte-addressable nonvolatile storage component based on resetting the QSPI component.

9. The memory device of claim 1, wherein the one or more components are further configured to:
determine a type of the internal reset that is to be performed; and
select one or more reset levels, of multiple potential reset levels, to be used for the internal reset based on determining the type of the internal reset that is to be performed.

10. The memory device of claim 9, wherein a first reset level, of the multiple potential reset levels, is associated with resetting non-host-interface components of the memory device, and
wherein a second reset level, of the multiple potential reset levels, is associated with resetting a host interface component of the memory device.

11. The memory device of claim 10, wherein the one or more components are further configured to:
determine whether the internal error is associated with the host interface component;
determine whether the memory device is associated with a fabric manager; and
perform one of:
select only the first reset level based on determining that the internal error is not associated with the host interface component;
select only the first reset level based on determining that the internal error is associated with the host interface component and that the memory device is not associated with the fabric manager; or
select the first reset level and the second reset level based on determining that the internal error is associated with the host interface component and that the memory device is associated with the fabric manager.

12. A method, comprising:
determining, by a memory device, that the memory device has encountered an internal error that requires an internal reset of at least one component of the memory device;
transmitting, by the memory device to a host device, a first-stage notification indicating that the memory device has encountered the internal error;
saving, by the memory device, diagnostic data associated with the internal error to a byte-addressable nonvolatile storage component of the memory device;
performing a first-stage reset of a first set of internal memory device subsystems; and
transmitting, by the memory device to the host device after the first-stage notification and based on performing the first-stage reset, a second-stage notification indicating that the host device is to perform a memory device reset procedure.

13. The method of claim 12, further comprising setting, by the memory device, a viral status bit in a designated vendor-specific extended capability (DVSEC) compute express link (CXL) status register,
wherein transmitting the first-stage notification includes transmitting the first-stage notification in response to setting the viral status bit in the DVSEC CXL status register.

14. The method of claim 12, wherein transmitting the first-stage notification includes:
forcing, by the memory device, a cyclic redundancy check error on a first flit transmitted by the memory device to the host device, and
setting, by the memory device, a viral bit in a second flit transmitted by the memory device to the host device.

15. The method of claim 12, wherein the second-stage notification indicates that the host device is to perform the memory device reset procedure using a reset-needed field of a memory device status register.

16. The method of claim 12, further comprising:
resetting, by the memory device, a quad serial peripheral interface (QSPI) component associated with the memory device; and
saving, by the memory device, the diagnostic data to the byte-addressable nonvolatile storage component based on resetting the QSPI component.

17. A compute express link (CXL) memory module, comprising:
one or more components configured to:
determine that the CXL memory module has encountered an internal error that requires an internal reset of at least one component of the CXL memory module;
transmit, to a host system, a first-stage notification indicating that the CXL memory module has encountered the internal error;
save diagnostic data associated with the internal error to a nonvolatile storage component of the CXL memory module;
determine a type of the internal reset that is to be performed;
select one or more reset levels, of multiple potential reset levels, to be used for the internal reset based on determining the type of the internal reset that is to be performed; and
perform a first-stage reset of a first set of internal memory device subsystems based on the one or more reset levels.

18. The CXL memory module of claim 17, wherein a first reset level, of the multiple potential reset levels, is associated with resetting non-host-interface components of the CXL memory module, and
wherein a second reset level, of the multiple potential reset levels, is associated with resetting a host interface component of the CXL memory module.

19. The CXL memory module of claim 18, wherein the one or more components are further configured to:
determine whether the internal error is associated with the host interface component;
determine whether the CXL memory module is associated with a CXL fabric manager; and
perform one of:
select only the first reset level based on determining that the internal error is not associated with the host interface component;
select only the first reset level based on determining that the internal error is associated with the host interface component and that the CXL memory module is not associated with the CXL fabric manager; or
select the first reset level and the second reset level based on determining that the internal error is associated with the host interface component and that the CXL memory module is associated with the CXL fabric manager.

20. The CXL memory module of claim 17, wherein the one or more components are further configured to transmit, to the host system after the first-stage notification and based on performing the first-stage reset, a second-stage notification indicating that the host system is to perform a memory module reset procedure.
